(19) United States
(12) Patent Application Publication
(10) Pub. No.: US 2011/0156169 A1
(43) Pub. Date: Jun. 30, 2011

(54) SEMICONDUCTOR APPARATUS CAPABLE OF REDUCING PLASMA DAMAGE

(75) Inventors: Won John CHOI, Ichon-shi (KR); Nam Gyu Ryu, Ichon-shi (KR)

(73) Assignee: Hynix Semiconductor Inc., Ichon-shi (KR)

(21) Appl. No.: 12/843,697

(22) Filed: Jul. 26, 2010

(30) Foreign Application Priority Data
Dec. 24, 2009 (KR) 10-2009-0130795

(51) Int. Cl. H01L 29/06; H01L 27/088

(52) U.S. Cl. 257/401; 257/503; 257/E29.012; 257/E27.06

(57) ABSTRACT

A semiconductor apparatus comprises a semiconductor substrate; a group of PMOS transistors formed on a predetermined portion of the semiconductor substrate; a group of NMOS transistors disposed adjacent to the group of PMOS transistors on the semiconductor substrate; a guard ring region formed between the group of PMOS transistors and the group of NMOS transistors; and a current detouring unit formed in the guard ring region and configured to discharge current produced by plasma ions towards the semiconductor substrate.

### CROSS-REFERENCE TO RELATED APPLICATION

The present application claims priority under 35 U.S.C. §119(a) to Korean Patent Application No. 10-2009-0130795, filed on Dec. 24, 2009, in the Korean Intellectual Property Office, which is incorporated herein by reference in its entirety as if set forth in full.

### BACKGROUND

1. Technical Field

Various aspects of the present disclosure generally relate to a semiconductor apparatus, and more particularly, to a semiconductor apparatus capable of reducing plasma damage.

2. Related Art

As the degree of integration of a semiconductor memory apparatus increases, the spacing and line width of circuit patterns constituting the semiconductor apparatus progressively decrease geometrically. Therefore, technologies for completely insulating and planarizing circuit patterns are key factors in determining the semiconductor apparatus' performance.

A semiconductor apparatus is also configured to have a multi-layered wiring structure. The semiconductor apparatus manufacturing processes require a low temperature in order to secure the performance of devices and wiring layers.

A high density plasma chemical vapor deposition (HDP CVD) for forming a layer of excellent gap-fill properties at a relatively low temperature (500 to 700° C.) is generally adopted in current semiconductor manufacturing processes.

Such an HDP CVD process produces a large amount of plasma ions to form layers which have dense layer quality.

The plasma ions produced during the HDP CVD process, however, may remain in a conductive region of a semiconductor substrate. For example, the plasma ions may remain on conductive wiring lines in a junction area, even after the HDP CVD process is completed. The remaining ions may flow between upper and lower conductive wiring lines and cause an unwanted current path. If this current path is directed to a transistor, mis-operation of the transistor may result.

### SUMMARY

In one aspect of the present invention, a semiconductor apparatus comprises a semiconductor substrate; a group of PMOS transistors formed on a predetermined portion of the semiconductor substrate; a group of NMOS transistors disposed adjacent to the group of PMOS transistors on the semiconductor substrate; a guard ring region formed between the group of PMOS transistors and the group of NMOS transistors; and a current detouring unit formed in the guard ring region and configured to discharge current produced by plasma ions towards the semiconductor substrate.

In another aspect of the present invention, a semiconductor apparatus comprises a semiconductor substrate; a driver formed on the semiconductor substrate and including a PMOS circuit element and an NMOS circuit element; and a current detouring unit connected to the driver and configured to discharge current produced by plasma ions towards the semiconductor substrate.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a sectional view of the major parts of a semiconductor apparatus, according to one embodiment of the invention;

FIG. 2 is a top view of a semiconductor driver, according to another embodiment of the invention; and

FIG. 3 is a sectional view taken along line III-III′ of FIG. 2.

### DETAILED DESCRIPTION

Advantages and characteristics of the present invention and a method for achieving them will be apparent with reference to embodiments described below in addition with reference to the accompanying drawings. However, the present invention is not limited to the exemplary embodiments described below but may be implemented in various forms. Therefore, the exemplary embodiments are provided to enable those skilled in the art to thoroughly understand the teaching of the present invention and to completely inform the scope of the present invention and the exemplary embodiment is just defined by the scope of the appended claims. Throughout the specification, like elements refer to like reference numerals.

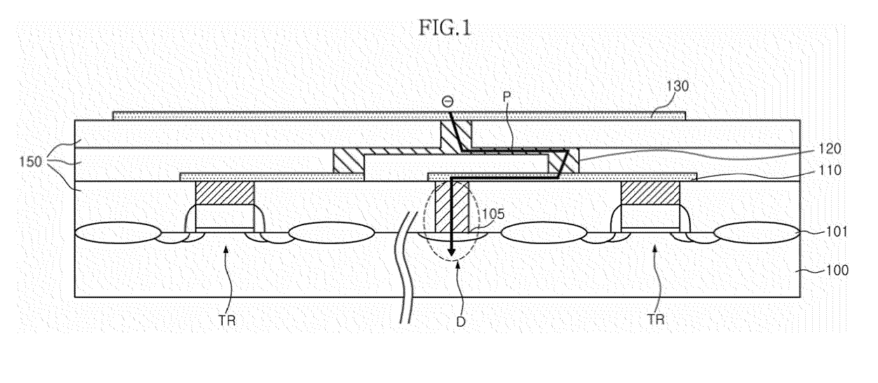

FIG. 1 is a sectional view of a semiconductor apparatus, according to one embodiment of the invention.

The semiconductor apparatus according to one embodiment comprises a current detouring unit D installed on a semiconductor substrate 100 to prevent the remaining plasma ions from flowing into a transistor.

The current detouring unit D is configured to change the flow of plasma ions. The plasma ions remain due to a HDP CVD process. If the flow were not changed, the ions would move to transistors TR through upper and lower wirings 130 and 110. Instead, they are directed towards the junction region of the semiconductor substrate 100.

The current detouring unit D may be a type of junction diode 105 integrated into the semiconductor substrate 100. The junction diode 105 is configured in a specific region of the semiconductor substrate 100 as an impurity region of a type opposite to the impurity type of the semiconductor substrate 100, and forms a p-n junction together with the semiconductor substrate 100.

Therefore, plasma ions remaining in the upper wiring 130 flow through the plug wiring 120 and the lower wiring 110 until they are discharged to the semiconductor substrate 100 via the junction diode D.

Reference numeral 101 refers to a device separation film, and reference numeral 150 refers to an insulating layer.

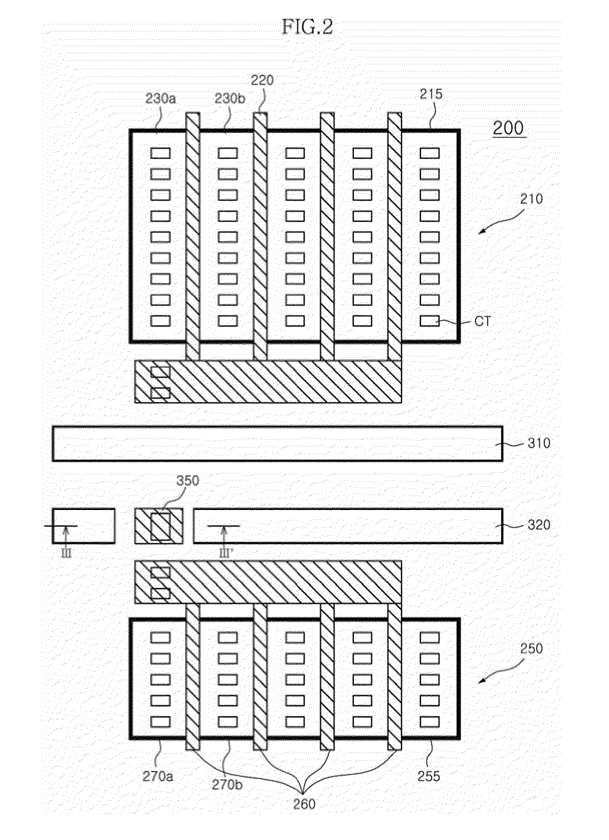

FIG. 2 is a top view of a semiconductor driver, according to another embodiment of the invention. A large amount of plasma ions may remain in a device with a large area, like a circuit region with PMOS transistors. According to the embodiment in FIG. 2, therefore, the current detouring unit D may be formed only in a driver region using PMOS transistors.

More specifically, the driver region 200 may comprise a PMOS region 210 and an NMOS region 250, which are arranged at a predetermined distance. It also comprises a current detouring unit D configured to detour and change the flow of plasma ions in the PMOS region 210 towards the semiconductor substrate.

The PMOS region 210 may comprise an active region 215 with p-type impurities, a plurality of gate electrodes 220 above the active region 215, and junction regions 230a and 230b. The junction regions are confined to the active region 215 between the plurality of gate electrodes 220. The plurality of gate electrodes 220 are parallel and are extended a predetermined height above the p-type active region 215. Each of one ends of gate electrodes 220 may be connected together.

The NMOS region 250 may comprise an active region 255 with n-type impurities, a plurality of electrode gates 260 arranged above the active region 255, and junction regions 270a and 270b. The junction regions are confined to the active region 255 between the plurality of gate electrodes 260. The plurality of gate electrodes 260 are parallel and are extended a predetermined height above the n-type active region 255. Each of one ends of the gate electrodes 260 may be connected together. Due to driving capability characteristics, the PMOS region 210 may have an area larger than that of the NMOS region 250. Reference characters CT refer to a contact unit connected with the wiring.

An undesirable parasitic bipolar transistor may be created between the PMOS region 210 and the NMOS region 250. Creation of such a parasitic bipolar transistor is referred to as latch-up. In order to prevent latch-up, guard rings 310 and 320 are formed in a substantially linear shape when the PMOS region 210 and the NMOS region 250 face each other. The guard rings 310 and 320 may be configured as a type of junction region. In order to prevent a parasitic path, the guard ring 310 adjacent to the PMOS region 210 (hereinafter, referred to as a PMOS guard ring) may be configured as an impurity region of substantially the same type as the semiconductor substrate or well of the PMOS region 210 (i.e., n-type impurity region). The guard ring 320 adjacent to the NMOS region 250 (hereinafter, referred to as an NMOS guard ring) may be configured as an impurity region of substantially the same type as the semiconductor substrate or well of the NMOS region 250 (i.e., p-type impurity region).

The current detouring unit D, according to the embodiment, may be formed in a region designated for the guard ring 310 or 320. Specifically, a current detouring unit D, i.e., junction diode, may be formed on a predetermined portion of the guard ring 310 or 320. Since the guard ring 310 or 320 has a substantially linear shape, installation of a current detouring unit D requires no additional area for the current detouring unit D.

The current detouring unit D must be insulated from the guard rings 310 and 320 when formed in their region. For the sake of even area utilization, the current detouring unit D is specifically formed in the guard ring 320 region of the NMOS region 250, which has an area smaller than that of the PMOS region 210.

For convenience of illustration, metal wiring for the connection between the PMOS region 210 and the NMOS region 250 is omitted from the drawings.

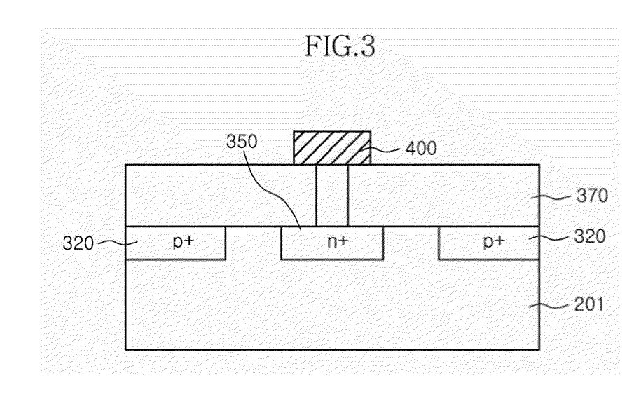

FIG. 3 is a sectional view taken along line III-III′ of FIG. 2, and illustrates the guard ring 320 of the NMOS region and the current detouring unit D.

Referring to FIG. 3, the NMOS guard ring 320 is formed on the semiconductor substrate 201 as a p-type impurity region, which is of substantially the same impurity type as the semiconductor substrate 201. The NMOS guard ring 320 according to the embodiment may be formed in a substantially linear shape through a mask process and an ion implantation process. During the mask process, the NMOS guard ring 320 may be provided with a cutout so that the current detouring unit D may be formed in a predetermined region of the NMOS guard ring 320. An n-type impurity region, which is of a type opposite to that of the NMOS guard ring 320, is then formed in the cutout to form a p-n junction. A current detouring unit D of a junction diode type is formed in this manner. Reference numeral 370 refers to a insulating layer.

Such a current detouring unit D of a junction diode type is connected with wiring 400 above the current detouring unit D, and effectively discharges plasma ions that may remain due to processes.

According to the embodiment, the current detouring unit D is installed only in a driver region having PMOS transistors, where the severest flow of plasma ions occurs. This reduces the number of current detouring units D and avoids any increase in the area of the semiconductor apparatus.

Furthermore, arrangement of the current detouring unit D in a predetermined area, i.e., in the guard ring region, requires no additional area for installation of the current detouring unit D.

The present invention is not limited to the above-mentioned embodiment.

Specifically, although the current detouring unit is installed in the NMOS guard ring region according to the embodiment, the location of installation is not limited thereto, but comprises any predetermined area, such as the PMOS guard ring region.

While certain embodiments have been described above, it will be understood to those skilled in the art that the embodiments described are by way of example only. Accordingly, the semiconductor apparatus capable of reducing plasma damage described herein should not be limited based on the described embodiments. Rather, the semiconductor apparatus capable of reducing plasma damage described herein should only be limited in light of the claims that follow when taken in conjunction with the above description and accompanying drawings.

What is claimed is:

1. A semiconductor apparatus comprising:
a semiconductor substrate;
a group of PMOS transistors formed on a predetermined portion of the semiconductor substrate;
a group of NMOS transistors disposed adjacent to the group of PMOS transistors on the semiconductor substrate;
a guard ring region formed between the group of PMOS transistors and the group of NMOS transistors; and
a current detouring unit formed in the guard ring region and configured to discharge current produced by plasma ions towards the semiconductor substrate.

2. The semiconductor apparatus according to claim 1, wherein the current detouring unit comprises an impurity region which has a type opposite to the semiconductor substrate and forms a p-n junction with the semiconductor substrate.

3. The semiconductor apparatus according to claim 2, wherein the guard ring region is formed in a substantially linear shape on the semiconductor substrate and is electrically insulated from the current detouring unit.

4. The semiconductor apparatus according to claim 3, wherein the guard ring region comprises:
a PMOS guard ring region disposed adjacent to the group of PMOS transistors; and
an NMOS guard ring region disposed adjacent to the group of NMOS transistors.

5. The semiconductor apparatus according to claim 4, wherein the current detouring unit is formed in the NMOS guard ring region and is electrically insulated from the NMOS guard ring region.

6. A semiconductor apparatus comprising:
a semiconductor substrate;
a driver formed on the semiconductor substrate and including a PMOS circuit element and an NMOS circuit element; and
a current detouring unit connected to the driver and configured to discharge current produced by plasma ions towards the semiconductor substrate.

7. The semiconductor apparatus according to claim 6, wherein the driver further comprises a guard ring region which is formed between the PMOS circuit element and the NMOS circuit element on the semiconductor substrate.

8. The semiconductor apparatus according to claim 7, wherein the guard ring region comprises:
a PMOS guard ring region having a substantially linear shape, formed adjacent to the PMOS circuit element, and including an n-type impurity region; and
an NMOS guard ring region having a substantially linear shape, formed adjacent to the NMOS circuit element, and including a p-type impurity region.

9. The semiconductor apparatus according to claim 8, wherein the current detouring unit is formed in the guard ring region and is electrically insulated from the guard ring region.

10. The semiconductor apparatus according to claim 9, wherein the current detouring unit is formed in the NMOS guard ring region and is electrically insulated from the NMOS guard ring region.

11. The semiconductor apparatus according to claim 10, wherein the NMOS guard ring region has a linear shape which is cut at a predetermined portion.

12. The semiconductor apparatus according to claim 11, wherein the current detouring unit is formed in the cut portion and comprises an impurity region forming a p-n junction with the semiconductor substrate.

13. The semiconductor apparatus according to claim 12, further comprising:
a conductive wiring line for transmitting an external signal,
wherein the current detouring unit is connected with the conductive wiring line.
